(19) United States
(12) Patent Application Publication
(10) Pub. No.: US 2025/0113538 A1
(43) Pub. Date: Apr. 3, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: YI CHEN LIN, Hsinchu (TW); Wei-Tse HSU, Hsinchu (TW); Ya-Ching TSENG, Hsinchu (TW)

(73) Assignee: Taiwan Semiconductor Manufacturing Company, Ltd., Hsinchu (TW)

(21) Appl. No.: 18/376,136

(22) Filed: Oct. 3, 2023

(51) Int. Cl. H01L 29/423; H01L 21/321; H01L 29/06; H01L 29/66; H01L 29/775; H01L 29/786

(52) U.S. Cl. CPC H10D 30/6735; H01L 21/3212; H10D 30/014; H10D 30/43; H10D 30/6757; H10D 62/121

(57) ABSTRACT

A semiconductor device includes a substrate, a first active structure, a second active structure, an epitaxy and a conductive via. The first active structure is formed on the substrate and including a plurality of first sheets and a plurality of first spacers. The second active structure is disposed formed on the substrate and adjacent to the first active structure, wherein the second active structure includes a plurality of second sheets and a plurality of second spacers, the second sheets and the second spacers are stacked to each other, and there is trench between the first active structure and the second active structure. The epitaxy is formed within the trench. The conductive via is connected with the epitaxy. The semiconductor device further has a planarized surface including the first active structure, the second active structure and the conductive via, and the planarized surface has a flatness less than 10 nm.

### BACKGROUND

In a semiconductor device, before a Chemical mechanical polishing (CMP), a layer may have a step which has several surfaces in different levels. However, excessive step will results in poor flatness of a CMP planarized surface.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic diagram of a semiconductor device according to an embodiment of the present disclosure; and

FIGS. 2A to 2K illustrate schematic diagrams of manufacturing processes of the semiconductor device of FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

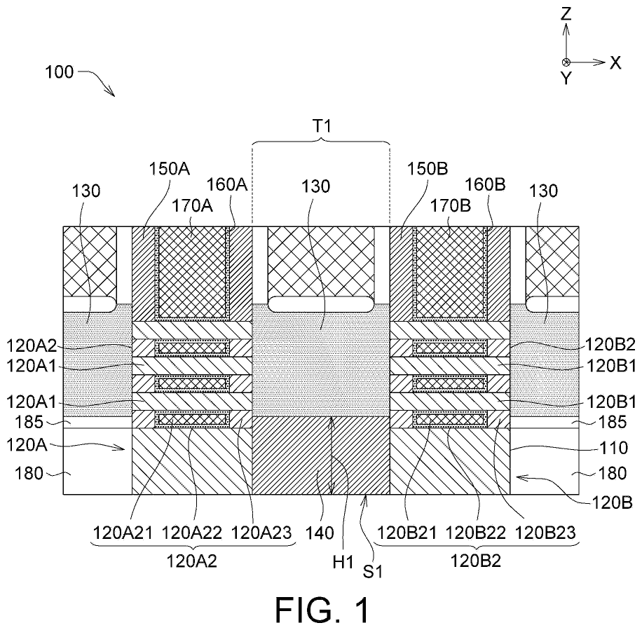

Referring to FIG. 1, a schematic diagram of a semiconductor device 100 according to an embodiment of the present disclosure is illustrated. The semiconductor device 100 includes, for example, at least one Gate-all-around (GAA) structure, at least one fork-sheet structure, etc.

As illustrated in FIG. 1, the semiconductor device 100 includes a substrate 110, a plurality of active structure (for example, at least one first active structure 120A and at least one second active structure 120B), at least one an epitaxy 130, at least one conductive via 140, at least one spacer layer (for example, at least one first spacer layer 150A and at least one second spacer layer 150B), at least one high-k dielectric layer (for example, at least one first high-k dielectric layer 160A and at least one second high-k dielectric layer 160B), at least one metal gate (for example, at least one first metal gate 170A and at least one second metal gate 170B), at least one pure silicon layer 180 and at least one block layer 185.

As illustrated in FIG. 1, the first active structure 120A and the second active structure 120B are formed on the substrate 110. There is a trench Tl between the adjacent first active structure 120A and second active structure 120B. The conductive via 140 is connected with the epitaxy 130. The conductive via 140 has a height H1. In an embodiment, the height H1 is, for example, less than 35 nanometers. In comparison with the length of the conductive via being greater than 35 nm (for example, 45 nm), the resistance of the conductive via 140 in the present embodiment may be reduced by, for example, 4% to 6%, or even greater.

As illustrated in FIG. 1, the semiconductor device 100 has a planarized surface S1 including the active structure, the conductive via 140 and the pure silicon layer 180, and the planarized surface S1 has a flatness, for example, equal to or less than 10 nm. In other words, the planarized surface S1 has the highest point and the lowest point, and the difference between the highest point and the lowest point is less than 10 nm. Due to the flatness of the planarized surface S1 being reduced to be 10 nm after CMP, the height H1 of the conductive via 140 may be reduced to be equal or less than 35 nm, for example.

As illustrated in FIG. 1, the first active structure 120A includes a plurality of first sheets (or channels) 120A1 and a plurality of first spacers (or composite layers) 120A2, wherein the first sheets 120A1 and the first spacers 120A2 are stacked to each other. For example, one of the first spacers 120A2 is formed between adjacent two of the first sheets 120A1. Each first spacer 120A2 includes a first metal 120A21, a first high-k dielectric portion 120A22 and a first inner spacer 120A23, wherein the first high-k dielectric portion 120A22 covers a portion of the first sheets 120A1, the first inner spacer 120A23 is formed on a lateral surface of the first high-k dielectric portion 120A22 or the first sheets 120A1. In addition, the first metal 120A21 may be formed of a material the same as that of the first metal gate 170A, and the first high-k dielectric portion 120A22 may be formed of a material the same as that of the first high-k dielectric layer 160A.

As illustrated in FIG. 1, the second active structure 120B includes a plurality of second sheets (channels) 120B1 and a plurality of second spacers 120B2, wherein the second sheets 120B1 and the second spacers 120B2 are stacked to each other. For example, one of the second spacers 120B2 is formed between adjacent two of the second sheets 120B1. The second spacer 120B2 includes a second metal 120B21, a second high-k dielectric portion 120B22 and a second inner spacer 120B23, wherein the second high-k dielectric portion 120B22 covers a portion of the second sheet 120B1, and the second inner spacer 120B23 is formed on a lateral surface of the second high-k dielectric portion 120B22 or the second sheet 120B1. In addition, the second metal 120B21 may be formed of a material the same as that of the second metal gate 170B, and the second high-k dielectric portion 120B22 may be formed of a material the same as that of the second high-k dielectric layer 160B.

As illustrated in FIG. 1, the epitaxy 130 may be a source or a drain of a transistor which includes the source, the drain and the metal gate. Each conductive via 140 is electrically connected with the corresponding epitaxy 130. In addition, the conductive via 140 may be called a back-side conductive via. The conductive via 140 may be formed of a material including metal or alloy thereof.

As illustrated in FIG. 1, the first spacer layer 150A is formed above the topmost first sheet 120A1, and isolates the first metal gate 170A from the epitaxy 130. The second spacer layer 150B is formed above the topmost second sheet 120B1, and isolates the second metal gate 170B from the epitaxy 130. In addition, the first high-k dielectric layer 160A is formed on the lateral surface of the first spacer layer 150A, and the second high-k dielectric layer 160B is formed on the lateral surface of the second spacer layer 150B. In addition, the first metal gate 170A fills a recess surrounded by the first high-k dielectric layer 160A or the first spacer layer 150A, and the second metal gate 170B fills a recess surrounded by the second high-k dielectric layer 160B or the second spacer layer 150B. The block layer 185 is formed on the pure silicon layer 180 and the epitaxy 130.

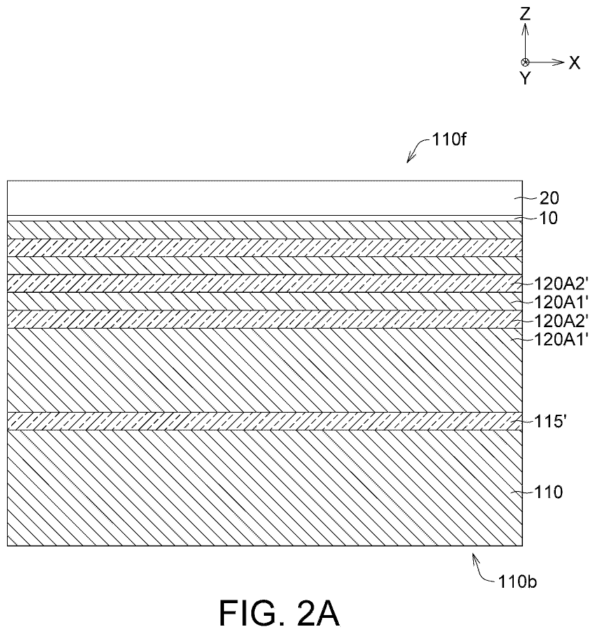

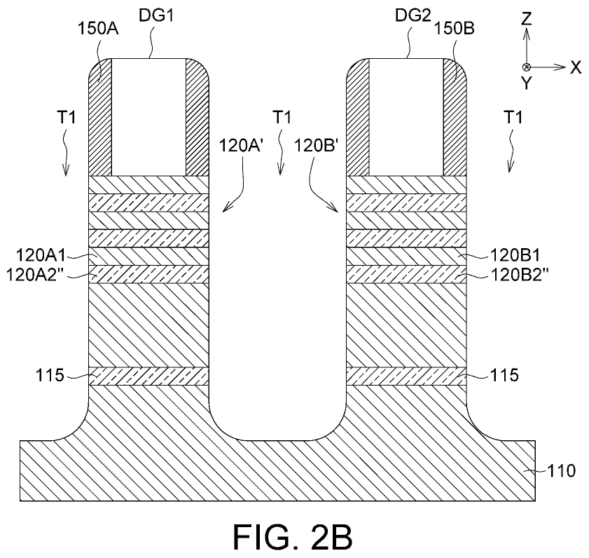

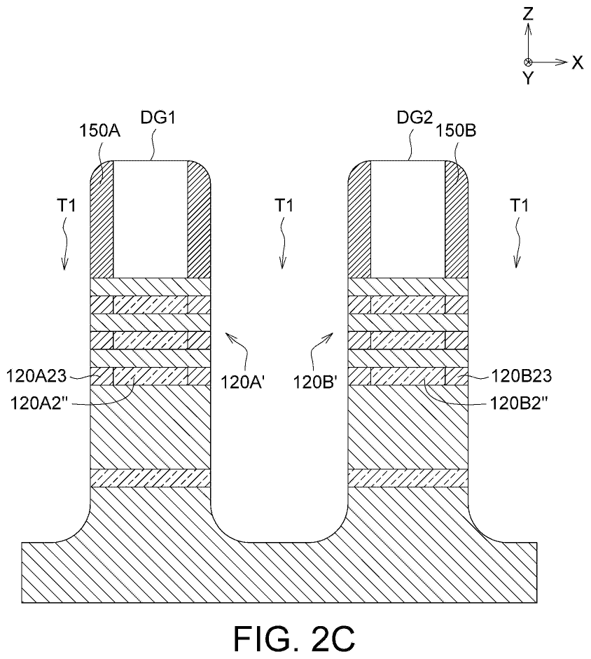

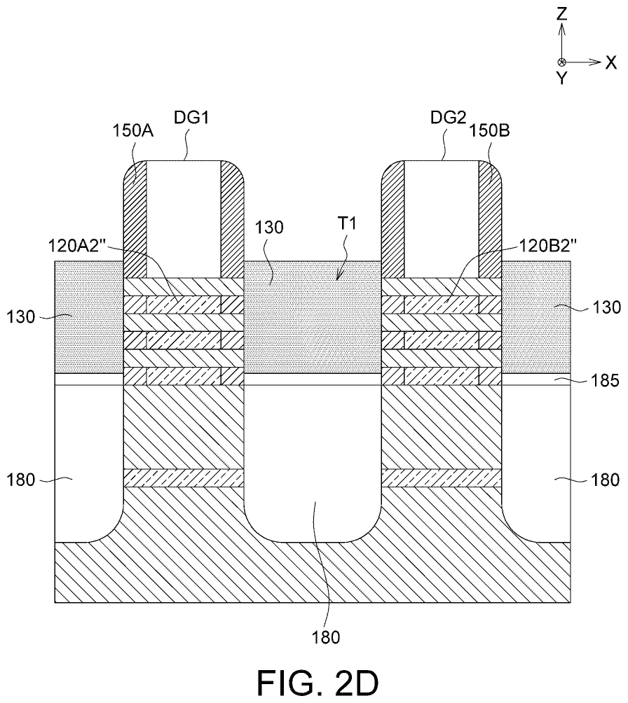

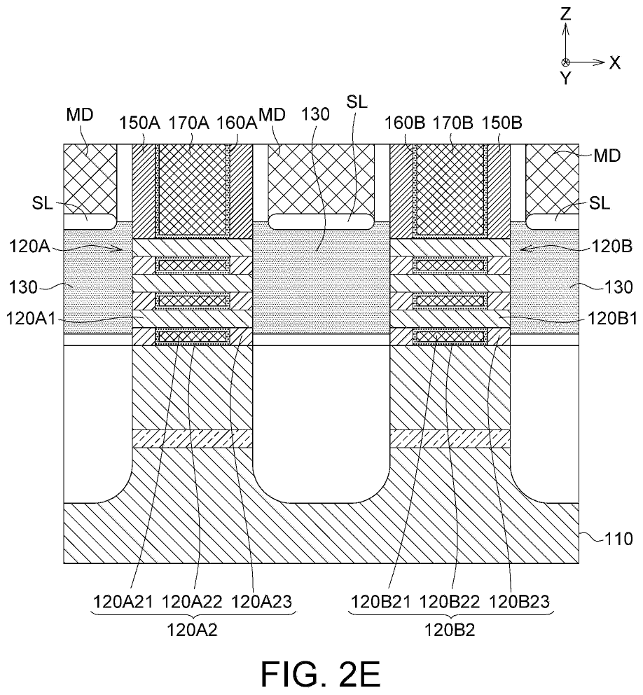

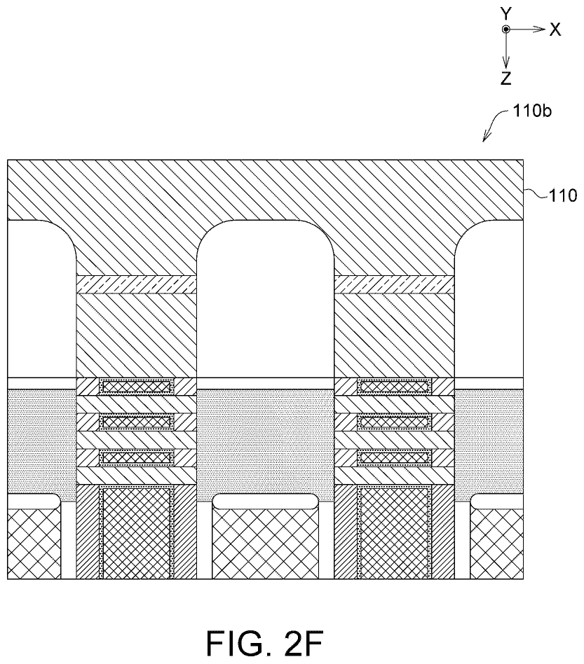

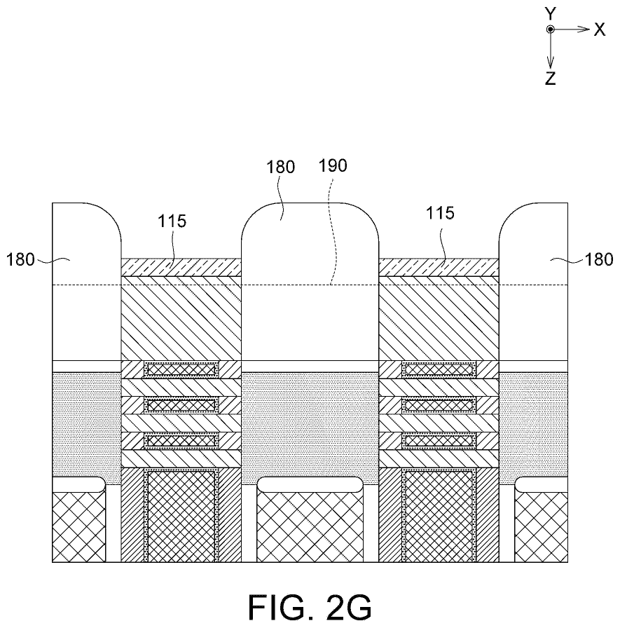

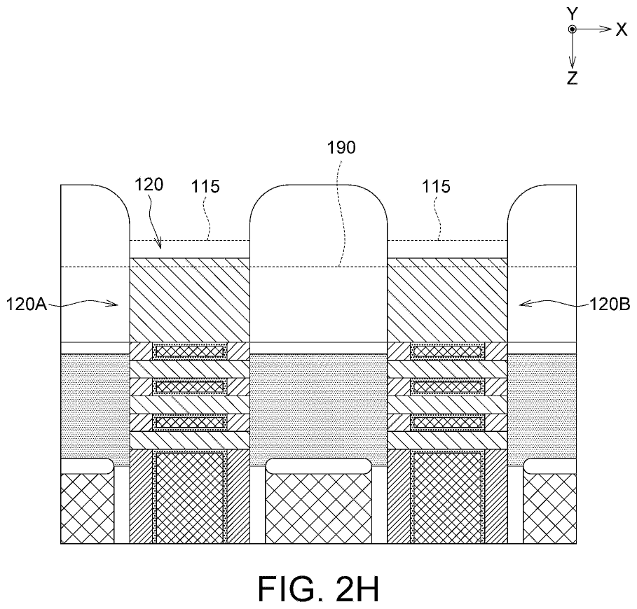

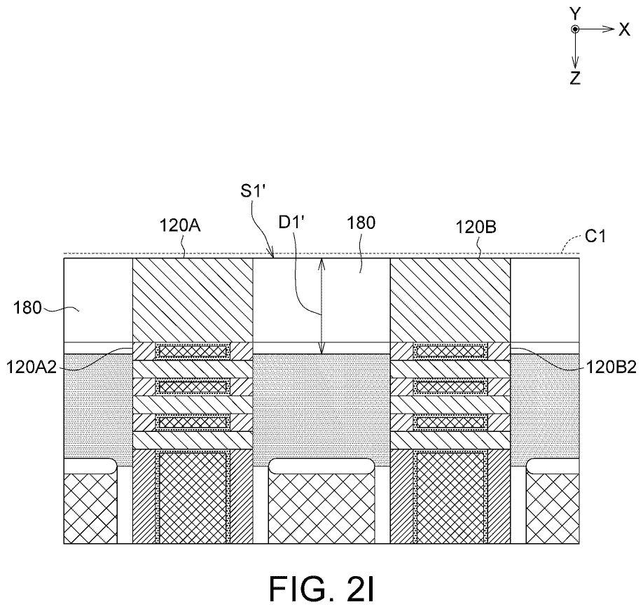

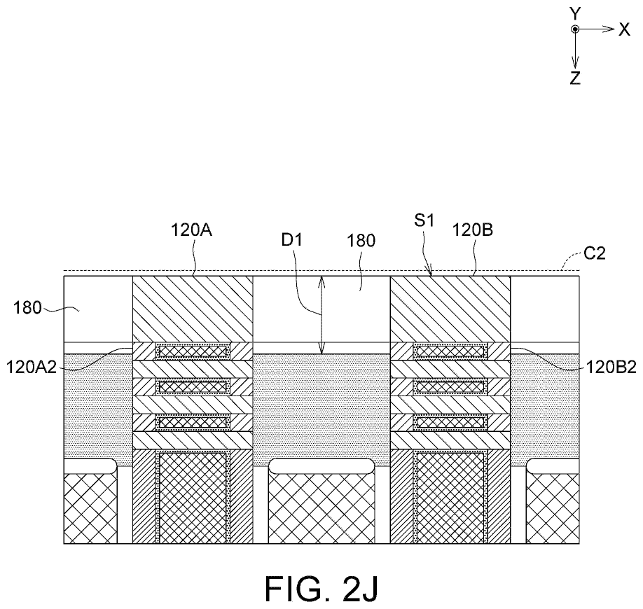

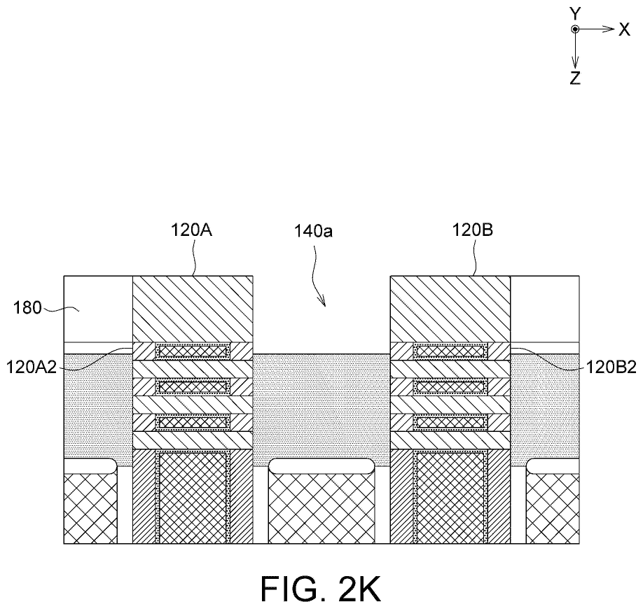

FIGS. 2A to 2K illustrate schematic diagrams of manufacturing processes of the semiconductor device 100 of FIG. 1.

As illustrated in FIG. 2A, an etching stop layer material 115′ is formed on the substrate 110 by using, for example, deposition. The substrate 110 is, for example, a silicon wafer. The etching stop layer material 115′ may be formed of a material including, for example, silicon germanium (SiGe). The substrate 110 has a front side 110f (for example, facing a direction in +Z axis) and a back side 110b (for example, facing a direction in-Z axis) opposite to the front side 110f. The etching stop layer material 115′ is formed on the front side 110f.

Then, as illustrated in FIG. 2A, a superlattice structure (for example, a plurality of sheet layers 120A1′ and a plurality of spacer layers 120A2′) is formed on the substrate 110 or the etching stop layer material 115′, wherein one spacer layer 120A2′ is formed between the adjacent two of the sheet layers 120A1′. Then, a pad oxide layer 10 and a hard mask 20 are formed over the stack structure of the sheet layers 120A1′ and the spacer layers 120A2′. The spacer layer may be formed of a material including, for example, silicon germanium, and the sheet layer may be formed of a material including, for example, silicon.

Then, although not illustrated, a portion of each sheet layer 120A1′ and a portion of each spacer layer 120A2′ are removed to form at least one interval through the patterned pad oxide layer 10 and hard mask 20 by using, for example, etching, etc. A remaining portion of each sheet layer 120A1′, a remaining portion of each spacer layer 120A2′ form at least one fin structure extending in the first direction (for example, X axis), and a plurality of the fin structures may be arranged in a second direction (for example, Y axis). The region of one fin structure defines one OD region, for example. Then, the pad oxide layer 10 and the hard mask 20 are removed by, for example, etching or CMP.

As illustrated in FIG. 2B, at least one first dummy gate structure DG1 and at least one first spacer layer 150A covering a lateral surface of the first dummy gate structure DG1 are formed on the superlattice structure, and at least one second dummy gate structure DG2 and at least one second spacer layer 150B covering a lateral surface of the second dummy gate structure DG2 are formed on the superlattice structure.

Then, as illustrated in FIG. 2B, at least one trench Tl passing through the etching stop layer material 115′, the stack structure and a portion of the substrate 110 is formed to form at least one etching stop layer 115, at least one first active structure 120A′ and at least one second active structure 120B′. The etching stop layer 115 is formed between the substrate 110 and the active structure. The first active structure 120A′ includes a plurality of the first sheets 120A1 and a plurality of first spacer 120A2″, wherein the first sheets 120A1 and the first spacer 120A2″ are stacked to each other. The second active structure 120B′ includes a plurality of the second sheets 120B1 and a plurality of second spacer 120B2″, wherein the second sheets 120B1 and the second spacer 120B2″ are stacked to each other.

As illustrated in FIG. 2C, a portion of the first spacer 120A2″ and a portion of the second spacer 120B2″ are removed to form a plurality of recesses by using, for example, etching. Then, the first inner spacers 120A23 are formed within the recesses of the first active structure 120A′, and the second inner spacers 120B23 are formed within the recesses of the second active structure 120B′ by, for example, depiction, etching back, etc.

As illustrated in FIG. 2D, the pure silicon layer 180 is formed within a bottom of the corresponding trench Tl by using, for example, epitaxy process. Then, at least one block layer 185 is formed on the pure silicon layer 180 by using, for example, deposition. The block layer 185 may be formed of a material including, nitride, etc. Then, the epitaxy 130 is formed on the block layer 185. The epitaxy 130 and the pure silicon layer 180 may be spaced from each other by the block layer 185.

As illustrated in FIG. 2E, the first dummy gate structure DG1 and the second dummy gate structure DG2 are removed to form a plurality of recesses by using, for example, dry etching, etc. Then, the first spacers 120A2″ of the first active structure 120A′ and the second spacers 120B2″ of the second active structure 120B′ in FIG. 2D are removed by using, for example, etching. Then, the first high-k dielectric layer 160A covering the first spacer layer 150A and the first high-k dielectric portion 120A22 covering a portion of the first sheet 120A1 are formed by, for example, ALD, etc. The second high-k dielectric layer 160B covering the second spacer layer 150B and the second high-k dielectric portion 120B22 covering the second sheet 120B1 are formed by, for example, ALD, etc. The first spacer layer 150A, the first high-k dielectric portion 120A2, the second spacer layer 150B and the second high-k dielectric portion 120B22 may be formed in the same process. Then, the first metal gate 170A within the recess surrounded by the first spacer layer 150A (or the first high-k dielectric layer 160A) and the first metal 120A21 within the recesses of the first active structure 120A′ are formed, and the second metal gate 170B within the recess surrounded by the second spacer layer 150B (or the second high-k dielectric layer 160B) and the second metal 120B21 within the recesses of the second active structure 120B′ are formed. Then, at least one silicide layer SL is formed on the epitaxy 130, and at least one metal over diffusion MD is formed over the silicide layer SL.

In FIG. 2E, the first metal 120A21, the first high-k dielectric portion 120A22 and the first inner spacer 120A23 may form the first spacer 120A2, and the second metal 120B21, the second high-k dielectric portion 120B22 and the second inner spacer 120B23 may form the second spacer 120B2. After forming the first spacer 120A2 and the second spacer 120B2, a plurality of the first sheet 120A1 and a plurality of the first spacers 120A2 form the first active structure 120A, and a plurality of the second sheet 120B1 and a plurality of the second spacers 120B2 form the second active structure 120B.

As illustrated in FIG. 2F, the structure of FIG. 2E is inverted to make the back side 110b of the substrate 110 face up.

As illustrated in FIG. 2G, at least one portion of the substrate 110 is removed to expose the etching stop layers 115 and the pure silicon layers 180 by using, for example, etching, such as wet etching (for example, wet cleaning). In process of etching, etchant may stop at the etching stop layers 115, and thus the silicon material layer may have the same level and excellent flatness based on the etching stop layers 115. In addition, an oxide layer 190 (extends in Y axis) which is formed in previous process may be located behind the pure silicon layers 180.

As illustrated in FIG. 2H, the etching stop layers 115 are removed to expose the first active structure 120A and the second active structure 120B by using, for example, etching.

As illustrated in FIG. 2I, the first active structure 120A (for example, silicon material of the first active structure 120A), the second active structure 120B (for example, silicon material of the second active structure 120B), the pure silicon layer 180 and the oxide layer 190 may be planarized (for silicon thinning) by using, for example, the first CMP C1. After the first CMP C1, a planarized surface (first planarized surface) S1′ is formed, and a first distance D1′ between the epitaxy 130 and the planarized surface S1′ may range between, for example, 40 nm and 45 nm. Due to different material property (for example, the oxide layer 190 and the active structures), the planarized surface S1′ may have a flatness greater than 10 nm. However, the follow-up second CMP C2 (see FIG. 2J) may improve the flatness.

As illustrated in FIG. 2J, the first active structure 120A (for example, silicon material of the first active structure 120A), the second active structure 120B (for example, silicon material of the second active structure 120B), the pure silicon layer 180 and the oxide layer 190 in FIG. 2I may be planarized by, for example, the second CMP C2. Compared with the first CMP C1, the second CMP C2 is soft or fine polishing or grinding. After the second CMP C2, the planarized surface (second planarized surface) S1 is formed, and a second height D1 between the epitaxy 130 and the planarized surface S1 may range between, for example, 30 nm and 40 nm, such as 35 nm. In addition, the planarized surface S1 has the flatness, for example, equal to or less than 10 nm, and accordingly the conductive vias 140 formed subsequently may have approximately the same heights.

As illustrated in FIG. 2K, the pure silicon layer 180, and the block layer 185 may be removed to form a hole 140a which exposes the epitaxy 130.

Then, the conductive via 140 is formed within the hole 140a by using a SPR (Super Power Rail) SAC (Self-Aligned Contact) process, as illustrated in FIG. 1.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes a first active structure, a second active structure disposed adjacent to the first active structure, an epitaxy and a conductive via. There is a trench between the first active structure and the second active structure. The conductive via is connected with the epitaxy. The conductive via has the height less than 35 nanometers. In comparison with the length of the conductive via being greater than 42 nm, the resistance of the conductive via 140 in the present embodiment may be reduced by, for example, 4% to 6%, or even greater.

Example embodiment 1: a semiconductor device includes a substrate, a first active structure, a second active structure, an epitaxy and a conductive via. The first active structure is formed on the substrate and including a plurality of first sheets and a plurality of first spacers, wherein the first sheets and the first spacers are stacked to each other. The second active structure is disposed formed on the substrate and adjacent to the first active structure, wherein the second active structure includes a plurality of second sheets and a plurality of second spacers, the second sheets and the second spacers are stacked to each other, and there is a trench between the first active structure and the second active structure. The epitaxy is formed within the trench. The conductive via is connected with the epitaxy. The semiconductor device further has a planarized surface including the first active structure, the second active structure and the conductive via, and the planarized surface has a flatness less than 10 nm.

Example embodiment 2 based on Example embodiment 1: the conductive via has a height less than 35 nanometers.

Example embodiment 3: a manufacturing method for a semiconductor device includes: forming an etching stop layer material, a plurality of sheet layers and a plurality of spacer layers on a substrate, wherein the sheet layers and the spacer layers are stacked to each other; forming a trench passing through the etching stop layer material, the sheet layers and the spacer layers to form a plurality of etching stop layers, a first active structure and a second active structure, wherein the first active structure includes a plurality of first sheets and a plurality of first spacers, the first sheets and the first spacers are stacked to each other, the second active structure includes a plurality of second sheets and a plurality of second spacers, the second sheets and the second spacers are stacked to each other; forming an epitaxy within the trench; and forming a conductive via to connect with the epitaxy, wherein the conductive via has a height equal to or less than 35 nm.

Example embodiment 4 based on Example embodiment 3: in forming the etching stop layer material, the sheet layers and the spacer layers on the substrate, the substrate has a front side and back side opposite to the front side, and the front side faces up; before forming the conductive via, the manufacturing method further includes: inverting the substrate, wherein the back side faces up.

Example embodiment 5 based on Example embodiment 3: in forming the etching stop layer material, the sheet layers and the spacer layers on the substrate, the etching stop layer material is formed of silicon germanium.

Example embodiment 6 based on Example embodiment 3: in forming the etching stop layer material, the sheet layers and the spacer layers on the substrate, the etching stop layer material and each spacer layer are formed of the same material.

Example embodiment 7 based on Example embodiment 3: before forming the epitaxy within the trench, the manufacturing method further includes: removing a portion of the substrate to expose the etching stop layers.

Example embodiment 8 based on Example embodiment 3: before forming the epitaxy within the trench, the manufacturing method further includes: etching a portion of the substrate by an etchant, wherein the etchant stops at the etching stop layers.

Example embodiment 9 based on Example embodiment 3: the manufacturing method further includes: removing the etching stop layers to expose the first active structure and the second active structure.

Example embodiment 10 based on Example embodiment 9: the manufacturing method further includes: planarizing the first active structure and the second active structure.

Example embodiment 11 based on Example embodiment 3: the manufacturing method further includes: planarizing the first active structure and the second active structure by a first CMP; and planarizing the first active structure and the second active structure by a second CMP.

Example embodiment 12 based on Example embodiment 11: in planarizing the first active structure and the second active structure by the first CMP, a first planarized surface is formed, and a first distance between the first planarized surface and the epitaxy ranges 40 nm and 45 nm; in planarizing the first active structure and the second active structure by the second CMP, a second planarized surface is formed, and a second distance between the second planarized surface and the epitaxy is equal to or less than 35 nm.

Example embodiment 13: a manufacturing method of a semiconductor device includes: forming an etching stop layer material, a plurality of sheet layers and a plurality of spacer layers on a substrate, wherein the sheet layers and the spacer layers are stacked to each other; forming a trench passing through the etching stop layer material, the sheet layers and the spacer layers to form a plurality of etching stop layers, a first active structure and a second active structure, wherein the first active structure includes a plurality of first sheets and a plurality of first spacers, the first sheets and the first spacers are stacked to each other, the second active structure includes a plurality of second sheets and a plurality of second spacers, the second sheets and the second spacers are stacked to each other; forming an epitaxy within the trench; planarizing the first active structure and the second active structure by a first CMP; and planarizing the first active structure and the second active structure by a second CMP, wherein the semiconductor device forms a planarized surface including the first active structure and the second active structure, and the planarized surface has a flatness less than 10 nm.

Example embodiment 14 based on Example embodiment 13: in planarizing the first active structure and the second active structure by the first CMP, a first planarized surface is formed, and a first distance between the first planarized surface and the epitaxy ranges 40 nm and 45 nm; in planarizing the first active structure and the second active structure by the second CMP, a second planarized surface is formed, and a second distance between the second planarized surface and the epitaxy is equal to or less than 35 nm.

Example embodiment 15 based on Example embodiment 13: the manufacturing method further includes: forming a conductive via to connect with the epitaxy, wherein the conductive via has a height equal to or less than 35 nm.

Example embodiment 16 based on Example embodiment 15: in forming the etching stop layer material, the sheet layers and the spacer layers on the substrate, the substrate has a front side and back side opposite to the front side, and the front side faces up; before forming the conductive via, the manufacturing method further includes: inverting the substrate, wherein the back side faces up.

Example embodiment 17 based on Example embodiment 13: in forming the etching stop layer material, the sheet layers and the spacer layers on the substrate, the etching stop layer material is formed of silicon germanium.

Example embodiment 18 based on Example embodiment 13: in forming the etching stop layer material, the sheet layers and the spacer layers on the substrate, the etching stop layer material and each spacer layer are formed of the same material.

Example embodiment 19 based on Example embodiment 13: the manufacturing method further includes: removing a portion of the substrate to expose the etching stop layers.

Example embodiment 20 based on Example embodiment 13: before forming the epitaxy within the trench, the manufacturing method further includes: etching a portion of the substrate by an etchant, wherein the etchant stops at the etching stop layers; and removing the etching stop layers to expose the first active structure and the second active structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first active structure formed on the substrate and comprising a plurality of first sheets and a plurality of first spacers, wherein the first sheets and the first spacers are stacked to each other;
a second active structure disposed formed on the substrate and adjacent to the first active structure, wherein the second active structure comprises a plurality of second sheets and a plurality of second spacers, the second sheets and the second spacers are stacked to each other, and there is a trench between the first active structure and the second active structure; and
an epitaxy formed within the trench;
a conductive via connected with the epitaxy; and
wherein the semiconductor device further has a planarized surface comprising the first active structure, the second active structure and the conductive via, and the planarized surface has a flatness less than 10 nm.

2. The semiconductor device as claimed in claim 1, wherein the conductive via has a height less than 35 nanometers.

3. A manufacturing method for a semiconductor device, comprising:
forming an etching stop layer material, a plurality of sheet layers and a plurality of spacer layers on a substrate, wherein the sheet layers and the spacer layers are stacked to each other;
forming a trench passing through the etching stop layer material, the sheet layers and the spacer layers to form a plurality of etching stop layers, a first active structure and a second active structure, wherein the first active structure comprises a plurality of first sheets and a plurality of first spacers, the first sheets and the first spacers are stacked to each other, the second active structure comprises a plurality of second sheets and a plurality of second spacers, the second sheets and the second spacers are stacked to each other;
forming an epitaxy within the trench; and
forming a conductive via to connect with the epitaxy, wherein the conductive via has a height equal to or less than 35 nm.

4. The manufacturing method as claimed in claim 3, wherein in forming the etching stop layer material, the sheet layers and the spacer layers on the substrate, the substrate has a front side and back side opposite to the front side, and the front side faces up; before forming the conductive via, the manufacturing method further comprises:
inverting the substrate, wherein the back side faces up.

5. The manufacturing method as claimed in claim 3, wherein in forming the etching stop layer material, the sheet layers and the spacer layers on the substrate, the etching stop layer material is formed of silicon germanium.

6. The manufacturing method as claimed in claim 3, wherein in forming the etching stop layer material, the sheet layers and the spacer layers on the substrate, the etching stop layer material and each spacer layer are formed of the same material.

7. The manufacturing method as claimed in claim 3, wherein before forming the epitaxy within the trench, the manufacturing method further comprising:
removing a portion of the substrate to expose the etching stop layers.

8. The manufacturing method as claimed in claim 3, wherein before forming the epitaxy within the trench, the manufacturing method further comprising:
etching a portion of the substrate by an etchant, wherein the etchant stops at the etching stop layers.

9. The manufacturing method as claimed in claim 3, further comprising:
removing the etching stop layers to expose the first active structure and the second active structure.

10. The manufacturing method as claimed in claim 9, further comprising:
planarizing the first active structure and the second active structure.

11. The manufacturing method as claimed in claim 3, further comprising:
planarizing the first active structure and the second active structure by a first Chemical mechanical polishing (CMP); and
planarizing the first active structure and the second active structure by a second CMP.

12. The manufacturing method as claimed in claim 11, wherein in planarizing the first active structure and the second active structure by the first CMP, a first planarized surface is formed, and a first distance between the first planarized surface and the epitaxy ranges 40 nm and 45 nm; in planarizing the first active structure and the second active structure by the second CMP, a second planarized surface is formed, and a second distance between the second planarized surface and the epitaxy is equal to or less than 35 nm.

13. A manufacturing method of a semiconductor device, comprising:
forming an etching stop layer material, a plurality of sheet layers and a plurality of spacer layers on a substrate, wherein the sheet layers and the spacer layers are stacked to each other;
forming a trench passing through the etching stop layer material, the sheet layers and the spacer layers to form a plurality of etching stop layers, a first active structure and a second active structure, wherein the first active structure comprises a plurality of first sheets and a plurality of first spacers, the first sheets and the first spacers are stacked to each other, the second active structure comprises a plurality of second sheets and a plurality of second spacers, the second sheets and the second spacers are stacked to each other;
forming an epitaxy within the trench;
planarizing the first active structure and the second active structure by a first CMP; and
planarizing the first active structure and the second active structure by a second CMP, wherein the semiconductor device forms a planarized surface comprising the first active structure and the second active structure, and the planarized surface has a flatness less than 10 nm.

14. The manufacturing method as claimed in claim 13, wherein in planarizing the first active structure and the second active structure by the first CMP, a first planarized surface is formed, and a first distance between the first planarized surface and the epitaxy ranges 40 nm and 45 nm; in planarizing the first active structure and the second active structure by the second CMP, a second planarized surface is formed, and a second distance between the second planarized surface and the epitaxy is equal to or less than 35 nm.

15. The manufacturing method as claimed in claim 13, further comprising:
forming a conductive via to connect with the epitaxy, wherein the conductive via has a height equal to or less than 35 nm.

16. The manufacturing method as claimed in claim 15, wherein in forming the etching stop layer material, the sheet layers and the spacer layers on the substrate, the substrate has a front side and back side opposite to the front side, and the front side faces up; before forming the conductive via, the manufacturing method further comprises:
inverting the substrate, wherein the back side faces up.

17. The manufacturing method as claimed in claim 13, wherein in forming the etching stop layer material, the sheet layers and the spacer layers on the substrate, the etching stop layer material is formed of silicon germanium.

18. The manufacturing method as claimed in claim 13, wherein in forming the etching stop layer material, the sheet layers and the spacer layers on the substrate, the etching stop layer material and each spacer layer are formed of the same material.

19. The manufacturing method as claimed in claim 13, wherein before forming the epitaxy within the trench, the manufacturing method further comprising:
removing a portion of the substrate to expose the etching stop layers.

20. The manufacturing method as claimed in claim 13, wherein before forming the epitaxy within the trench, the manufacturing method further comprising:
etching a portion of the substrate by an etchant, wherein the etchant stops at the etching stop layers; and
removing the etching stop layers to expose the first active structure and the second active structure.
